(19) United States
(12) Patent Application Publication
(10) Pub. No.: US 2015/0014808 A1
(43) Pub. Date: Jan. 15, 2015

(54) SEMICONDUCTOR STRUCTURE AND FABRICATION METHOD THEREOF

(71) Applicant: UNITED MICROELECTRONICS CORP., Hsin-Chu City (TW)

(72) Inventors: Shih-Hung Tsai, Tainan City (TW); Rai-Min Huang, Taipei City (TW); I-Ming Tseng, Kaohsiung City (TW); Yu-Ting Lin, Nantou County (TW); Chien-Ting Lin, Hsinchu City (TW)

(21) Appl. No.: 13/939,204

(22) Filed: Jul. 11, 2013

(51) Int. Cl. H01L 21/762; H01L 21/311; H01L 29/06

(52) U.S. Cl. CPC H01L 21/76224; H01L 29/0649; H01L 21/311
USPC 257/506; 438/424

(57) ABSTRACT

A fabrication method for a semiconductor structure at least includes the following steps. First, a pattern mask with a predetermined layout pattern is formed on a substrate. The layout pattern is then transferred to the underneath substrate so as to form at least a fin-shaped structure in the substrate. Subsequently, a shallow trench isolation structure is formed around the fin-shaped structure. Afterwards, a steam oxidation process is carried out to oxidize the fin-shaped structure protruding from the shallow trench isolation and to form an oxide layer on its surface. Finally, the oxide layer is removed completely.

### BACKGROUND OF THE INVENTION

1. Field of the Invention

The present invention generally relates to the field of non-planar semiconductor structures, and more particular to a semiconductor structure having fin-shaped structures with multiple slanted surfaces and a method for fabricating the same.

2. Description of the Prior Art

With the increasing miniaturization of semiconductor devices, various multi-gate MOSFET devices have been developed. The multi-gate MOSFETs are advantageous for the following reasons. First, the manufacturing processes of the multi-gate MOSFET devices can be integrated into traditional logic device processes easily, and thus are more compatible. In addition, since the three-dimensional structure of a multi-gate MOSFET increases the overlapping area between the gate and the substrate, its channel region can be controlled more effectively. This therefore reduces drain-induced barrier lowering (DIBL) effect and short channel effect (SCE). Moreover, the channel region is longer for a similar gate length. Therefore, the current between the source and the drain is increased.

Please refer to FIG. 1. FIG. 1 is a schematic, cross-sectional diagram showing a conventional multi-gate transistor after the formation of fin structures. As shown in FIG. 1, conventional fabrication processes for multi-gate transistors usually include the following steps. At the beginning of the fabrication process, a patterned mask 12 is formed on the substrate 10. Subsequently, an etching process is carried out by using the patterned mask 12 as an etch mask. Through this process, several fin structures 20 can be defined in the substrate 10. In the subsequent processes, a shallow trench isolation (STI) structure may be further formed between each fin structures 20 so as to electrically isolate each fin structure. However, as sizes and dimensions of the fin structures 20 continuously scale down, areas over the top surfaces 12a of each patterned mask 12 are reduced correspondingly. In this configuration, the patterned mask 12 may not be able to bear the subsequent polishing process for the shallow trench isolation structure. Besides, the patterned mask 12 may partially shift or collapse due to the reduced area over the underneath fin structure 20. Consequently, how to fabricate the required fin structures without having the patterned mask shift or collapse is one of the important issues in semiconductor industry.

### SUMMARY OF THE INVENTION

To this end, on object of the present invention is to provide a semiconductor device and a fabrication method thereof so as to overcome the drawbacks of conventional technologies.

According to a preferred embodiment of the invention, a fabrication method for a semiconductor structure is provided. The fabrication method includes at least the following steps. First, a pattern mask with a predetermined layout pattern is formed on a substrate. The layout pattern is then transferred to the underneath substrate so as to form at least a fin-shaped structure in the substrate. Subsequently, a shallow trench isolation structure is formed around the fin-shaped structure. Afterwards, a steam oxidation process is carried out to oxidize the fin-shaped structure protruding from the shallow trench isolation and to form an oxide layer on its surface. Finally, the oxide layer is removed completely.

According to another preferred embodiment of the present invention, a semiconductor structure is provided. The semiconductor structure includes a fin structure and a shallow trench isolation structure. The fin structure is disposed on a substrate, wherein any sidewall of the fin structure includes at least two slanted surfaces, and an interface is formed between the slanted surfaces. The top surface of the shallow trench isolation structure is substantially leveled with the interface.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a schematic, cross-sectional diagram showing a conventional multi-gate transistor after the formation of fin structures.

FIG. 2 to FIG. 7 are schematic diagrams showing a method for fabricating a semiconductor structure according to preferred embodiments of the present invention.

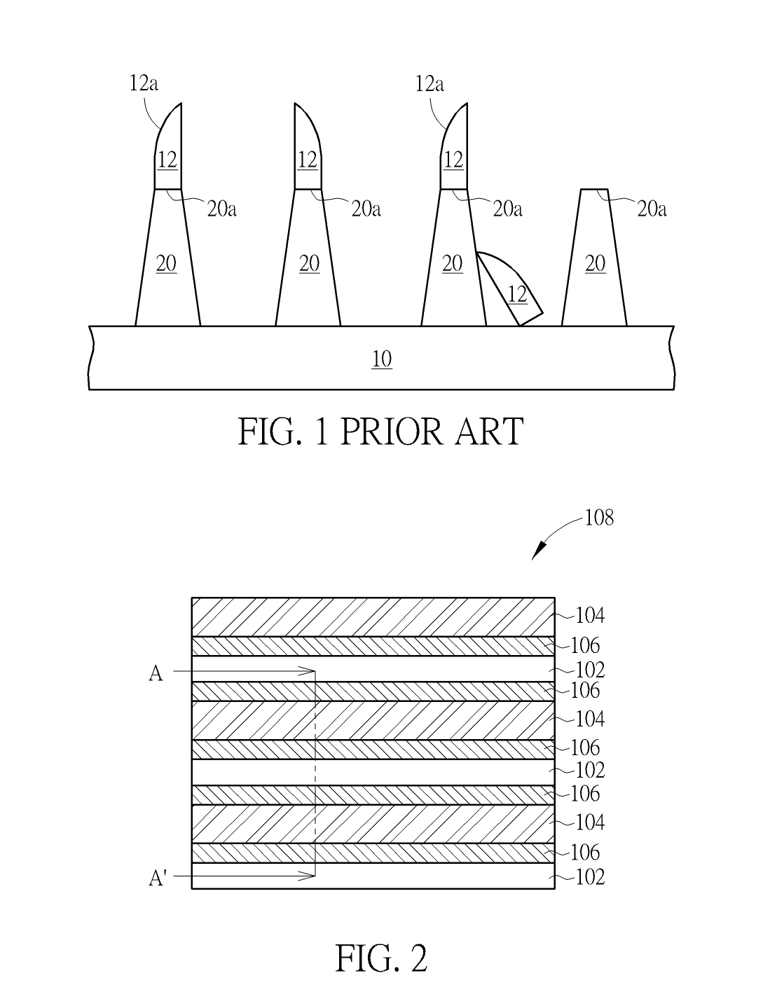

### DETAILED DESCRIPTION

In the following description, numerous specific details are given to provide a thorough understanding of the invention. It will, however, be apparent to one skilled in the art that the invention may be practiced without these specific details. Furthermore, some well-known system configurations and process steps are not disclosed in detail, as these should be well-known to those skilled in the art.

Likewise, the drawings showing embodiments of the apparatus are not to scale and some dimensions are exaggerated for clarity of presentation. Also, where multiple embodiments are disclosed and described as having some features in common, like or similar features will usually be described with same reference numerals for ease of illustration and description thereof

FIG. 2 to FIG. 7 are schematic diagrams showing a method for fabricating a semiconductor structure according to preferred embodiments of the present invention. Please refer to FIG. 2 and FIG. 3. FIG. 3 is a schematic diagram taken along a line A-A′ in FIG. 2. At the beginning of the fabrication processes, a substrate 100, on which an optional pad layer 102, a plurality of sacrificial layers 104 and a plurality of patterned masks 106 are stacked sequentially, is provided. Each sacrificial layer 104 may be stripe-shaped and their long axes may be parallel to one another or there are acute angles or obtuse angles among them, but not limited thereto. According to this embodiment, the patterned masks 106 may be spacers disposed on the sidewalls of the sacrificial layers 104. In this way, the patterned masks 106 could be extended along the sidewalls of the sacrificial layers 104 and has a closed loop layout pattern 108. In addition, if another suitable etching process is adopted to remove portions of the patterned masks 106, it can change the layout pattern 108 from the closed loop appearance to the stripe appearance.

According to this embodiment, a spacer self-aligned double patterning (SADP) technology is applied. Through this technology, the layout pattern 108 defined by the patterned masks 106 may be further transferred to the substrate 100. Preferably, dimensions of sacrificial layers 104 are greater than or equal to the minimum exposure limit of the corresponding photolithographic process, while dimensions of patterned masks 106 are less than these “minimum exposure limit” and have “sub-lithographic feature”, but not limited thereto. The layout pattern may also be formed in the substrate through other kinds of double pattering process.

The substrate 100 may be a semiconductor substrate (such as a silicon substrate), a silicon containing substrate (such as a silicon carbide substrate), a III-V group-on-silicon (such as GaN-on-silicon) substrate, a graphene-on-silicon substrate, a silicon-on-insulator (SOI) substrate or an epitaxial layer containing substrate. The pad layers 102 are made of a dielectric layer, such as silicon oxide layer or a silicon nitride layer, but not limited thereto. The sacrificial layers 104 may be made of silicon material, III-V group semiconductors or other suitable semiconductor materials, and preferably be made of polysilicon material. For example, when the composition of the sacrificial layers 104 is polysilicon, the fabrication processes may includes depositing a polysilicon layer on the substrate and patterning the polysilicon layer through a photolithographic process and an etching process. As a result, the sacrificial layers 104 can be obtained. The detailed description of these processes is omitted for the sake of clarity. The patterned masks 106 may be made of silicon oxide, silicon nitride, oxynitride, silicon carbide or other suitable dielectric materials different from pad layers 102 and sacrificial layers 104. The method for forming the patterned masks 106 may include the following steps. First, a material layer (not shown) is conformally formed on the sacrificial layers 104 and the substrate. Then, the material is etched through a selective etching process until the patterned masks 106 are formed on the sidewalls of the sacrificial layers 104. The detailed description of these processes is omitted for the sake of clarity.

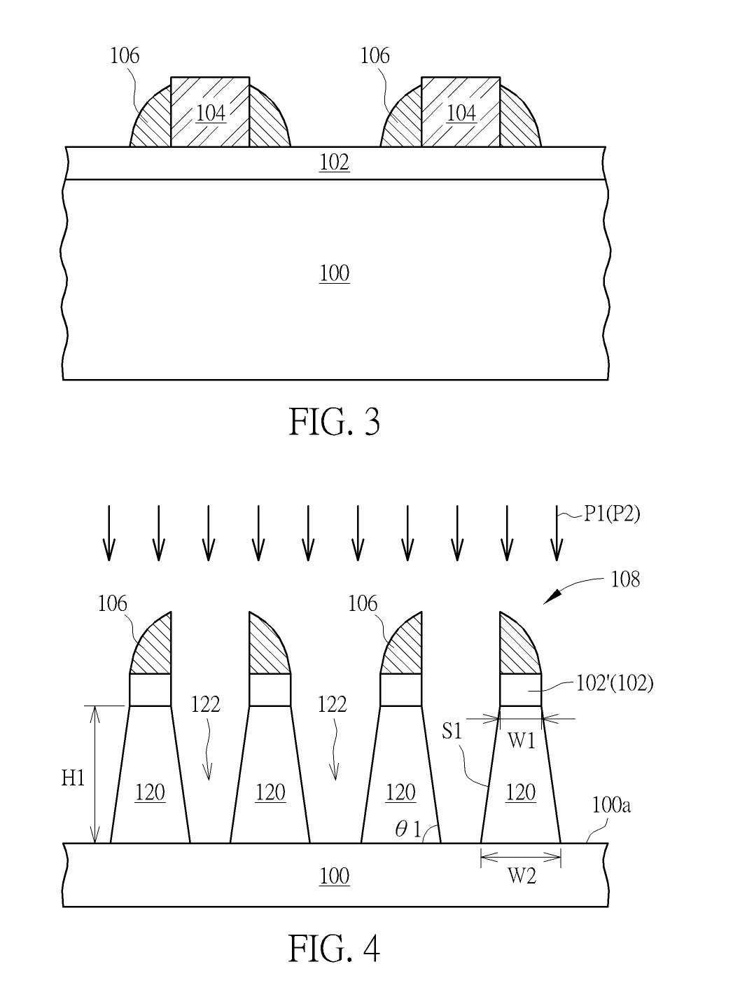

After the formation of the patterned mask 106, each sacrificial layer 104 is removed subsequently so as to expose the pad layer 102 underneath the sacrificial layers 104. Please refer to FIG. 4. FIG. 4 is a schematic diagram after the formation of the fin structures according to a first preferred embodiment of the present invention. As shown in FIG. 4, after the removal of the sacrificial layers 104, at least an etching process is carried out such that the layout pattern 108 defined by the patterned mask 106 may be sequentially transferred to the pad layer 102 and the substrate 100. For example, an etching process P1 may be performed to etch the substrate 100. For example, an etching process P1 may be carried out by using the patterned masks 106 as etch mask. Through sequentially etching the pad layer 102 and the substrate 100, patterned pad layers 102′, fin structures 120 and shallow trench 122 may be formed. More precisely, the etching process P1 may be a dry etching process, a wet etching process or a combination thereof. According to this embodiment, the etching process P1 is a fluoride-containing etching process, so that fluoride can accumulate on the sidewalls S1 of the fin structures 120 during the etching process, and the etching of the sidewalls S1 can therefore be restrained, thereby achieving fin structures 120 with slanted sidewalls; that is, the fin structures 120 have taper profiles. In addition, the degree of slant of the sidewalls could be modified by adjusting the etching selectivity or the height difference among patterned masks 106, the pad layer 102 and the substrate 100.

Refer now to FIG. 4. When the etching process P1 is accomplished, another oxidation process P2, such as a steam oxidation process, may be further carried out. Such that the surfaces of the fin structures 120 can be oxidized and the slope of the fin structures 120 may be further reduced. More precisely, the steam oxidation process may be an in-situ steam generation (ISSG) and a recipe of which may at least include water and oxygen, but not limited thereto. For the sake of clarity, there are only four fin structures depicted in this embodiment, while this number should not be used to restrict the invention. That is to say, the number of the fin structures may be increased or reduced if required.

At this time, through applying the etching process P1 and the optional oxidation process P2, fin structures 120 with trapezoidal profiles may be obtained. In other words, the width W1 of the top surface of the fin structure 120 is narrower than its bottom surface width W2. Besides, a first angle (also called first acute angle θ1) is defined between the sidewall S1 of each fin structure 120 and the top surface 100a of the substrate. The first angle is inside the fin structure 120. More precisely, the width W1 of the top surface preferably ranges between 5-10 nanometers (nm), more preferably ranges between 8-10 nm, while the first acute angle θ1 preferably ranges between 60-90 degrees, more preferably at 70 degrees. Besides, the fin structures 120 preferably have a first height H1 greater than 100 Angstroms. Since the width W1 of the top surface of the fin structures 120 is wide enough to support the above the patterned pad layers 102′and patterned masks 106, it can prevent patterned mask layers from shifting or collapsing.

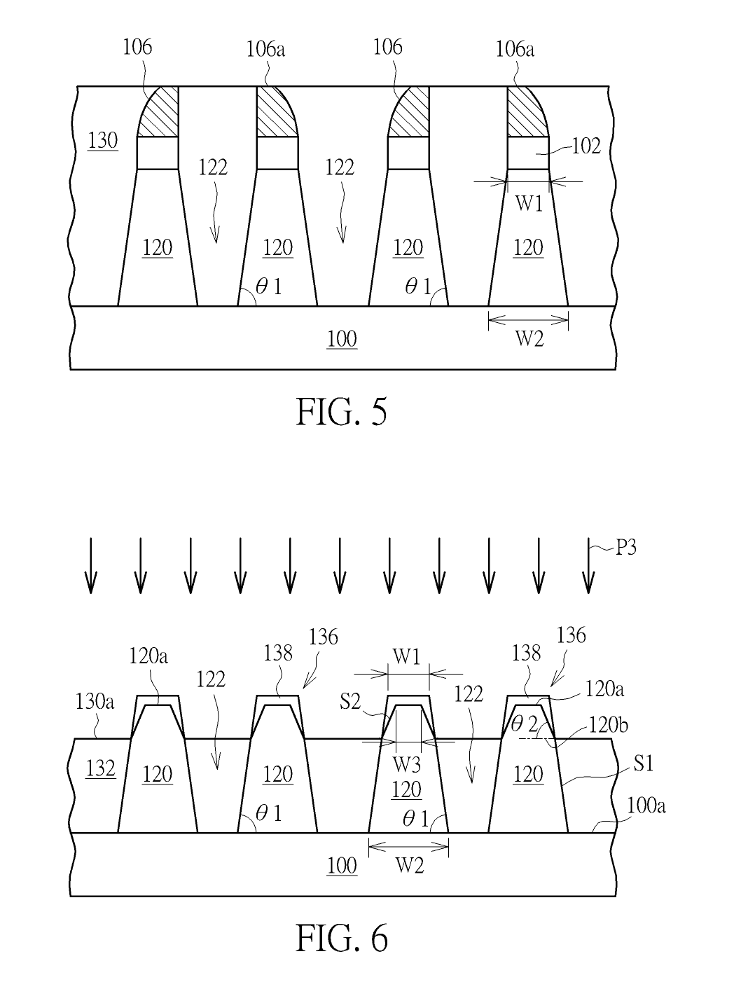

Please refer to FIG. 5. Subsequently, an insulating layer 130 is blank deposited on the substrate so as to fill up each shallow trench 122 and cover the patterned mask 106 and the fin structures 120. Afterwards, a polishing process, such as a chemical mechanical process (CMP), is carried out to planarize the insulating layer 130 until a top surface 106a of each patterned mask is exposed. It should be noted that, since the width of the bottom of the patterned mask 106 is at least greater than 4 nm, preferably between 5-10 nm, the patterned masks 106 can sustain the pressure imposed during the polishing process. The process utilized to form an insulating layer 130 includes a high density plasma CVD (HDPCVD) process, a sub atmosphere CVD (SACVD) process, a spin on dielectric (SOD) process or a flowable chemical vapor deposition (FCVD) process, but not limited thereto.

After the polishing process, an etching back process may be applied to etch the insulating layer 130. The patterned masks 106 are then removed to expose the top surface of the patterned pad layers 102′or the fin structures 120. According to various product requirements, an optional ion implantation process may be further carried out before or after the removal of the patterned masks 106. In this way, a well (not shown) of a conductivity type different from that of the substrate may be formed in the fin structures 120, but not limited thereto.

Please refer to FIG. 6. Through performing the above-mentioned etching back process, a shallow trench isolation structure 132 could be therefore formed in the shallow trench 122 such that top portion 136 of each fin structure 120 could protrude from the shallow trench isolation structure 132. Subsequently, an oxidation process shown in FIG. 6 is carried out. The oxidation process, for example, is a steam oxidation process P3, which is able to oxidize the fin structures 120 protruding from the shallow trench isolation structure 132 so as to form an oxide layer 138 on its surface. According to this embodiment, the thickness of the oxide layer 138 gradually increases from bottom to top so that the width of each fin structure 120 may be further reduced. For example, the steam oxidation process P3 may be an in-situ steam generation (ISSG) process. The recipe of which may at least include water and oxygen and the processing temperature of which may range from 750° C. to 1000° C. More precisely, when defining a surface leveled with the top surface 130a of the shallow trench isolation structure as a bottom surface 120b and comparing the ratio of the width W3 to the width W1 before and after the steam oxidation process P3, it comes out that the ratio of the width of the top surface 120a to that of the bottom surface 120b approximately ranges from ⅓ to ½ before the steam oxidation process P3, whereas the ratio of the width of the top surface 120a to that of the bottom surface 120b approximately ranges from ¼ to ⅓ after the steam oxidation process P3. Therefore, a second angle (also called second acute angle θ2) between the sidewall S2 of the top portion and the top surface 130a of the shallow trench isolation structure 132 is smaller than first acute angle θ1. The second angle is defined as an angle inside the fin structure 120. In other words, through applying the steam oxidation process P3, the sidewalls S2 of each fin structure top portion 136 may become more slanted.

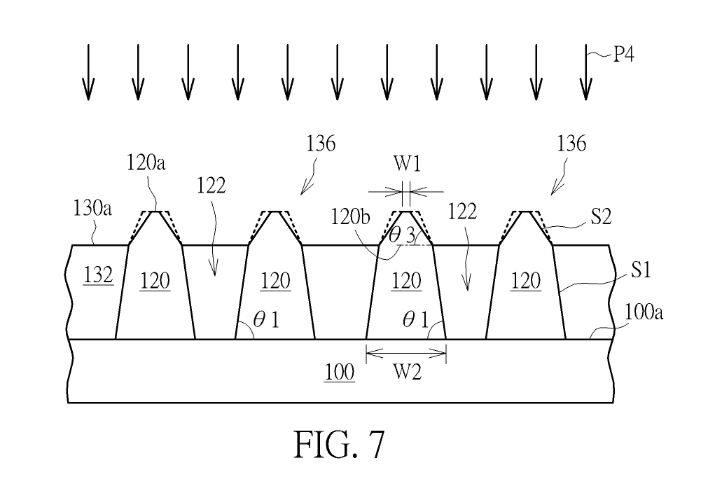

The oxide layer 138 is then removed and the subsequent process is carried out. Please refer to FIG. 7. an optional surface treatment process P4 is carried out. In this way, the defects on the surface of each fin structure 120 may be amended and the width W3 of the top portion is further reduced. A recipe of the surface treatment process P4 preferably includes hydrogen and nitrogen, but not limited thereto. At this time, there is a third angle, also called third acute angle θ3, between the sidewall S2 of the top portion and the top surface 130a of the shallow trench isolation structure. The relationship between the first acute angle θ1 to the third acute angle θ3 may be as follows: third acute angle θ3<second acute angle θ2<first acute angle θ1. Besides, before performing the surface treatment process P4, a doped channel region (not shown) may be formed in the top portions 136 of the fin structures. The processes for forming the doped channel region may include an ion implantation process and a thermal treatment process. More precisely, the temperature of the thermal treatment preferably ranges from 900° C. to 1200° C. The conductivity type of the doped channel region is preferably different from that of the optionally formed well.

Once all the above processes are accomplished, a semiconductor structure according to the preferred embodiments of the present invention is therefore obtained. The semiconductor structure disclosed herein includes at least a fin structure 120 and a shallow trench isolation structure 132 around the fin structure 120. Both the fin structure 120 and the shallow trench isolation structure 132 are disposed on the substrate 100. Moe precisely, any sidewall of the fin structure 120 includes at least two slanted surfaces. An interface is formed between and adjacent to the slanted surfaces such that the top surface 130a of the shallow trench isolation structure is able to align the interface. Preferably, the slanted surfaces at least include a first slanted surface and a second slanted surface from bottom to top, i.e. the slanted surfaces correspond to a first sidewall S1 and a second sidewall S2. There is a first acute angle θ1 between the first slanted surface and the top surface 100a of the substrate, while there is a second acute angle θ2 between the second slanted surface and the top surface 130a of the shallow trench isolation structure. The first acute angle θ1 is greater than the second acute angle θ2. In addition, when a surface treatment process P4 is carried out, the second acute angle θ2 is greater than the third acute angle θ3.

According to the preceding paragraphs, if using the semiconductor structure as portions of non-planar MOSFET, the related semiconductor processes may be carried out subsequently, such as processes for fabricating MOSFET with semiconductor gates or metal gates. For example, in a case that applying a gate-first process, at least a stripe-shaped gate stack structure crossing the semiconductor structure may be formed. More precisely, the gate stack structure may include a gate dielectric layer, a gate conductive layer and a cap layer from bottom to top. Then, spacers are respectively formed on two sides of the gate stack structure. Afterwards, processes, such as an implantation process for source/drain, deposition process for interlayer dielectric and a process for contact plug, may be carried out sequentially in order to fabricate required transistor. In another case that a gate-last process is applied, the gate stack structure described above may be further removed after the deposition of the interlayer dielectric. Through this process, a trench may be left between the two opposite spacers. Afterwards, a high-k dielectric layer and a metal conductive layer are filled into the trench sequentially in order to fabricate required metal gate transistor.

According to the above embodiments, either gate-first process or gate-last process can be adopted as a main semiconductor process. In either case, there are three contact faces between each fin structure and the following formed dielectric layer serving as a carrier channel region. Compared with planar MOSFETs, the tri-gate MOSFETs have wider channel width within the same channel length. When a driving voltage is applied, the tri-gate MOSFET may produce an on-current twice higher than conventional planar MOSFETs

In addition, although only the non-planar transistors are disclosed in the preceding paragraphs, it should not be regarded as restrictions on the present invention. Without departing from the scope and the spirit of the present invention, the present invention could be also applied to various patterned structures or devices with high densities and integrities, such as conductive structures, electrical connecting structures and so forth.

To summarize, the present invention provides a semiconductor structure and a method for fabricating the same through the above-described embodiments. Through performing a steam oxidation process after the formation of the shallow trench isolation structure, fin structures protruding from the shallow trench isolation structure may be oxidized and sidewalls of top portions of each fin structures may become more slanted. In this way, the shift or collapse of the patterned masks due to insufficient supporting areas may be avoided. Furthermore, since each fin structure has a gradually slanted surface, which leads to relatively wide bottom surface between each fin structure and the substrate, the fin structure can be fixed to the substrate more firmly and the collapse of which is therefore avoided.

Those skilled in the art will readily observe that numerous modifications and alterations of the device and method may be made while retaining the teachings of the invention. Accordingly, the above disclosure should be construed as limited only by the metes and bounds of the appended claims.

1. A method for fabricating a semiconductor structure, comprising:
forming at least a patterned mask on a substrate, wherein the patterned mask has a layout pattern;
transferring the layout pattern into the substrate so as to form at least a fin structures in the substrate;
forming a shallow trench isolation structure around the fin structures;
performing a steam oxidation process so as to oxidize the fin structure protruding from the shallow trench isolation structure and form an oxide layer; and
completely removing the oxide layer.

2. The method according to claim 1, further comprising a pad layer disposed between the patterned mask and the substrate.

3. The method according to claim 2, further comprising transferring the layout pattern into the pad layer so as to form a patterned pad layer.

4. The method according to claim 3, further comprising removing the patterned pad layer before performing the steam oxidation process.

5. The method according to claim 1, further comprising performing another steam oxidation process before forming the shallow trench isolation structure.

6. The method according to claim 1, wherein a step for forming the shallow trench isolation structure comprises:
blank depositing an insulating layer, conformally covering the patterned mask and the fin structure;
polishing the insulating layer until the patterned mask is exposed; and
performing an etching process until a top portion of the fin structure protrudes from the insulating layer.

7. The method according to claim 1, wherein a top portion of the fin structure protrudes from the shallow trench isolation structure before performing the steam oxidation process, wherein the top portion comprises a top surface and a bottom surface, and a ratio of a width of the top surface to a width of the bottom surface ranges from ⅓ to ½.

8. The method according to claim 7, wherein the bottom surface of the top portion is leveled with a top surface of the shallow trench isolation structure.

9. The method according to claim 7, wherein a ratio of the width of the top surface to the width of the bottom surface ranges from ¼ to ⅓ after completely removing the oxide layer.

10. The method according to claim 1, wherein a recipe of the steam oxidation process comprises water and oxygen.

11. The method according to claim 1, wherein a temperature of the steam oxidation process ranges from 750° C. to 1000° C.

12. The method according to claim 1, further comprising performing at least an ion implantation process before completely removing the oxide layer.

13. The method according to claim 1, wherein a thickness of the oxide layer gradually increase from bottom to top.

14. The method according to claim 1, wherein a top portion of the fin structure protrudes from the shallow trench isolation structure after completely removing the oxide layer, wherein the top portion comprises a top surface and a bottom surface, a ratio of a width of the top surface to a width of the bottom surface ranging from ¼ to ⅓.

15. The method according to claim 1, further comprising performing a thermal treatment after completely removing the oxide layer.

16. The method according to claim 15, wherein a temperature of the thermal treatment ranges from 900° C. to 1200° C.

17. The method according to claim 1, further comprising performing a surface treatment after completely removing the oxide layer, wherein a recipe of the surface treatment comprises hydrogen and nitrogen.

18. A semiconductor structure, comprising:
a fin structure, disposed on a substrate, wherein at least one of sidewalls of the fin structure comprises at least two slanted surfaces, and an interface is formed between the slanted surfaces; and
a shallow trench isolation structure, disposed on the substrate and around the fin structure, wherein a top surface of the shallow trench isolation structure is substantially leveled with the interface.

19. The structure according to claim 18, wherein the slanted surfaces at least comprise a first slanted surface and a second slanted surface, a first angle is defined between the first slanted surface and the top surface of the substrate, a second angle is defined between the second slanted surface and the top surface of the shallow trench isolation structure, wherein the first angle is greater than the second angle, and both the first angle and the second angle are in the fin structures.

20. The structure according to claim 18, wherein the fin structure has a profile shrinking from bottom to top.
